(19) United States
(12) Patent Application Publication
(10) Pub. No.: US 2018/0145196 A1
(43) Pub. Date: May 24, 2018

(54) SOLAR CELL AND METHOD OF MANUFACTURING THE SAME

(71) Applicant: LG Electronics Inc., Seoul (KR)

(72) Inventors: Jungmin HA, Seoul (KR); Sungyeon CHO, Seoul (KR); Sangwook PARK, Seoul (KR)

(21) Appl. No.: 15/821,026

(22) Filed: Nov. 22, 2017

(30) Foreign Application Priority Data
Nov. 23, 2016 (KR) 10-2016-0156790

(51) Int. Cl. H01L 31/048; H01L 31/0236; H01L 31/0352; H01L 31/18

(52) U.S. Cl. CPC H01L 31/048; H01L 31/1868; H01L 31/0352; H01L 31/02363

(57) ABSTRACT

Disclosed is a solar cell including a semiconductor substrate having a first surface and a second surface that is opposite the first surface, each of which includes a first edge area, a second edge area, and a cell area located between the first and second edge areas, a first passivation layer formed on the cell area of the first surface of the semiconductor substrate, a first conductive semiconductor layer disposed on the first passivation layer, and a first electrode disposed on the first conductive semiconductor layer. The first edge area of the first surface of the semiconductor substrate is exposed.

### CROSS-REFERENCE TO RELATED APPLICATION

This application claims the priority benefit of Korean Patent Application No. 10-2016-0156790, filed on Nov. 23, 2016 in the Korean Intellectual Property Office, the disclosure of which is incorporated herein by reference.

### TECHNICAL FIELD

The present disclosure relates to a solar cell and a method of manufacturing the same, and more particularly, to a solar cell having an improved structure and a method of manufacturing the same.

### BACKGROUND

Recently, due to depletion of existing energy resources, such as oil and coal, interest in alternative sources of energy to replace the existing energy resources is increasing. Most of all, solar cells are popular next generation cells to convert sunlight into electrical energy.

Solar cells may be manufactured by forming various layers and electrodes based on some design. The efficiency of solar cells may be determined by the design of the various layers and electrodes. In order for solar cells to be commercialized, it is necessary to overcome the low efficiency thereof. Therefore, there is a need to maximize the efficiency of solar cells.

Meanwhile, a method of manufacturing a solar cell includes a process of dividing a semiconductor substrate. In this semiconductor substrate dividing process, a laser may be used to divide the semiconductor substrate. However, the dividing process using the laser may cause deterioration in the solar cell due to the laser.

### SUMMARY

According to one aspect of the present disclosure, the above and other objects can be accomplished by the provision of a solar cell including a semiconductor substrate having a first surface and a second surface that is opposite the first surface, each of which includes a first edge area, a second edge area, and a cell area located between the first and second edge areas, a first passivation layer formed on the cell area of the first surface of the semiconductor substrate, a first conductive semiconductor layer disposed on the first passivation layer, and a first electrode disposed on the first conductive semiconductor layer, wherein the first edge area of the first surface of the semiconductor substrate is exposed, and in the exposed edge area of the first surface, the semiconductor substrate has a uniform doping concentration in a depth direction thereof.

According to another aspect of the present disclosure, there is provided a method of manufacturing a solar cell, the method including disposing a mask on a scribing portion of a semiconductor substrate having a plurality of cell portions and the scribing portion located between the cell portions, forming a first conductive area on the semiconductor substrate and the mask, forming a first electrode on the first conductive area so as to be electrically connected to the conductive area, removing the mask so as to remove a portion of the first conductive area disposed on the mask, and dividing the semiconductor substrate along the scribing portion.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view illustrating a solar cell according to some implementations of the present disclosure;

FIGS. 2 to 11 are cross-sectional views and plain views for explaining a method of manufacturing the solar cell according to some implementations of the present disclosure;

FIG. 12 is a cross-sectional view illustrating a solar cell according to some implementations of the present disclosure;

FIGS. 13 to 18 are cross-sectional views and plain views for explaining a method of manufacturing the solar cell according to some implementations of the present disclosure;

FIG. 19 is a cross-sectional view illustrating a solar cell according to some implementations of the present disclosure;

FIGS. 20 to 23 are cross-sectional views and plain views for explaining a method of manufacturing the solar cell according to some implementations of the present disclosure; and

FIG. 24 is a cross-sectional view illustrating a solar cell according to some implementations of the present disclosure.

### DETAILED DESCRIPTION

Reference will now be made in detail to the implementations of the present disclosure, examples of which are illustrated in the accompanying drawings. However, the present disclosure is not limited to these implementations, and of course, may be altered in various forms.

In the drawings, to clearly and briefly explain the present disclosure, illustration of elements having no connection with the description is omitted, and the same or extremely similar elements are designated by the same reference numerals throughout the specification. In addition, in the drawings, for more clear explanation, the thickness, the width, and the like are exaggerated or reduced, and the thickness, width, and the like of the present disclosure are not limited to the illustration of the drawings.

In addition, in the entire specification, when an element is referred to as “including” another element, the element should not be understood as excluding other elements so long as there is no special conflicting description, and the element may include at least one other element. In addition, it will be understood that, when an element such as a layer, film, region or substrate is referred to as being “on” another element, it can be directly on the other element or intervening elements may also be present. On the other hand, when an element such as a layer, film, region or substrate is referred to as being “directly on” another element, this means that there are no intervening elements therebetween.

Hereinafter, a solar cell according to some implementations of the present disclosure will be described in detail with reference to the accompanying drawings.

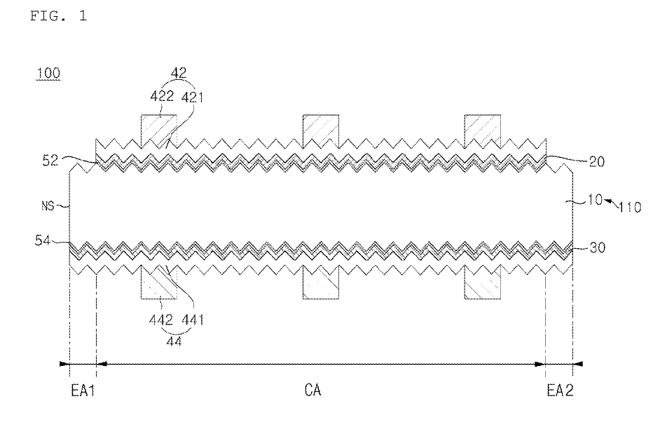

FIG. 1 is a cross-sectional view illustrating a solar cell according to some implementations of the present disclosure.

Referring to FIG. 1, the solar cell 100 according to the present implementation may include a semiconductor substrate 110 including a base area 10, a first passivation layer 52 formed on a first surface of the semiconductor substrate 110, a second passivation layer 54 formed on a second surface of the semiconductor substrate 110, a first conductive area 20 formed on the first passivation layer 52 at the first surface side of the semiconductor substrate 110, a second conductive area 30 formed on the second passivation layer 54 at the second surface side of the semiconductor substrate 110, a first electrode 42 electrically connected to the first conductive area 20, and a second electrode 44 electrically connected to the second conductive area 30. Although the first surface and the second surface may be opposite each other, and the first surface may be a light incidence surface of the solar cell 100, the technical feature of the present disclosure is not limited thereto.

In the present implementation, each of the first surface and the second surface of the semiconductor substrate 110 includes first and second edge areas EA1 and EA2, and a cell area CA between the first and second edge areas EA1 and EA2. Each of the first and second edge areas EA1 and EA2 may be the area that is adjacent to a side surface NS, which connects the first surface and the second surface of the semiconductor substrate 110 to each other.

In the present implementation, the first and second edge areas EA1 and EA2 of the first surface of the semiconductor substrate 110 may be the area in which no conductive area or no passivation layer is disposed, and the cell area CA of the first surface of the semiconductor substrate 110 may be the area in which a semiconductor layer such as the passivation layer is disposed. Thus, in the present implementation, the semiconductor substrate 110 may be exposed through the first and second edge areas EA1 and EA2 of the first surface. In addition, the first and second edge areas EA1 and EA2 of the semiconductor substrate 110 may have the same doping concentration in the depth direction, and the crystalline structure of the semiconductor substrate 110 may differ between the first and second edge areas EA1 and EA2 of the first surface and the first and second edge areas EA1 and EA2 of the second surface. A more detailed description related thereto will be provided later.

The semiconductor substrate 110 may be formed of crystalline semiconductors. In one example, the semiconductor substrate 110 may be formed of monocrystalline or polycrystalline semiconductors (e.g., monocrystalline or polycrystalline silicon). In particular, the semiconductor substrate 110 may be formed of monocrystalline semiconductors (e.g., a monocrystalline semiconductor wafer, and more specifically, a monocrystalline silicon wafer). When the semiconductor substrate 110 is formed of monocrystalline semiconductors (e.g., monocrystalline silicon), the solar cell 100 configures a monocrystalline semiconductor solar cell (e.g., a monocrystalline silicon solar cell). Such a solar cell 100 may have excellent electrical properties because it is based on the semiconductor substrate 110 having high crystallinity and thus low defects.

In the present implementation, the semiconductor substrate 110 may include only the base area 10 without including a separate doped area. When the semiconductor substrate 110 includes no doped area, for example, damage to the semiconductor substrate 110 or an increase in the number of defects, which may occur when forming a doped area, may be prevented, whereby the semiconductor substrate 110 may have an excellent passivation property. Thereby, surface recombination, which may occur in the surface of the semiconductor substrate 110, may be minimized.

In the present implementation, the semiconductor substrate 110 or the base area 10 may be doped with a first conductive dopant, which is a base dopant, at a low doping concentration, thus being of a first conductive type. At this time, the semiconductor substrate 110 or the base area 10 may have a lower doping concentration, higher resistance, or lower carrier concentration than the first conductive area 20, which is of the same conductive type as the semiconductor substrate 110 or the base area 10.

The first surface and/or the second surface of the semiconductor substrate 110 may be subjected to texturing in order to prevent reflection. Thereby, both the first surface and the second surface of the semiconductor substrate 110 may prevent the reflection of light introduced thereinto. Therefore, the solar cell 100 of the present implementation having a bi-facial structure may effectively reduce shading loss. However, the present disclosure is not limited thereto, and only one of the first surface and the second surface of the semiconductor substrate 110 may be subjected to texturing.

As described above, each of the first surface and the second surface of the semiconductor substrate 110 includes the first and second edge areas EA1 and EA2, and the cell area CA between the first and second edge areas EA1 and EA2. The first and second edge areas EA1 and EA2 of the first surface of the semiconductor substrate 110 may be exposed, thus including a damaged area. The damaged area may be caused by laser irradiation. In some implementations, the first and second edge areas EA1 and EA2 included in the first surface of the semiconductor substrate 110 may be coupled to each other when viewing the solar cell 100 in a plain view. In some other implementations, the first and second edge areas EA1 and EA2 included in the second surface of the semiconductor substrate 110 may be coupled to each other when viewing the solar cell 100 in a plain view.

In addition, the first and second edge areas EA1 and EA2 of the first surface of the semiconductor substrate 110 and the first and second edge areas EA1 and EA2 of the second surface may have different crystalline structures. Specifically, the crystalline structure of the first and second edge areas EA1 and EA2 of the first surface of the semiconductor substrate 110 may be larger than the crystalline structure of the first and second edge areas EA1 and EA2 of the second surface. This may be realized via laser irradiation for wafer scribing. That is, when attempting laser scribing through the first surface of the semiconductor substrate 110, the first and second edge areas EA1 and EA2 of the first surface may have a damaged area due to laser irradiation, and the crystalline structure in the damaged area may become larger than the crystalline structure of the first and second edge areas EA1 and EA2 of the second surface.

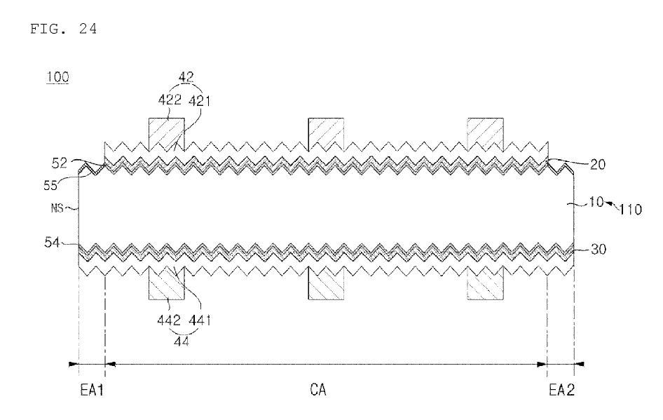

FIG. 24 is a cross-sectional view illustrating a solar cell according to some implementations of the present disclosure. Furthermore, referring FIG. 24, an oxide(55) may be formed on the exposed first and second edge area(EA1 and ES2). Also The oxide(55) may be a silicon oxide

Meanwhile, in the present disclosure, the first and second edge areas EA1 and EA2 of the first surface of the semiconductor substrate 110 may have a consistent doping concentration in the depth direction thereof. This is a structural feature derived from the method of manufacturing the present disclosure, and will be described later in more detail with relation to the manufacturing method, which will be described later.

The first passivation layer 52 is formed on the first surface of the semiconductor substrate 10, and the second passivation layer 54 is formed on the second surface of the semiconductor substrate 10. Thereby, each of the first surface and the second surface of the semiconductor substrate may be passivated.

In the present implementation, the first passivation layer 52 may not be formed in the first and second edge areas EA1 and EA2 on the first surface of the semiconductor substrate 110. However, the technical sprit of the present disclosure is not limited thereto. In another implementation of the present disclosure, the first passivation layer 52 may extend to the first and second edge areas EA1 and EA2 of the first surface so as to cover the first and second edge areas EA1 and EA2 on the first surface. A more detailed description will be provided later.

In this specification, although the terms “the first passivation layer 52” and “the second passivation layer 54” are used, the first passivation layer 52 and the second passivation layer 54 may also serve as tunneling layers. That is, the first and second passivation layers 52 and 54 may serve as a barrier for electrons and holes so as to prevent minority carriers from passing therethrough, and to allow only majority carriers, which accumulate at a portion adjacent to the first and second passivation layers 52 and 54 and thus have a given amount of energy or more, to pass therethrough. In one example, the first and second passivation layers 52 and 54 may include intrinsic amorphous semiconductors. For example, the first and second passivation layers 52 and 54 may be formed as intrinsic amorphous silicon (i-a-si) layers. As such, since the first and second passivation layers 52 and 54 include the same semiconductor material as the semiconductor substrate 110 and have properties similar to those of the semiconductor substrate 110, the surface properties of the semiconductor substrate 110 may be more effectively improved. Thereby, the passivation property thereof may be greatly improved. However, the present disclosure is not limited thereto. Thus, the first and/or second passivation layers 52 and 54 may include an intrinsic amorphous silicon carbide (i-a-SiCx) layer or an intrinsic amorphous silicon oxide (i-a-SiOx) layer.

At this time, the first and second passivation layers 52 and 54 may be formed respectively throughout the first surface and the second surface of the semiconductor substrate 110. Thereby, the first surface and the second surface of the semiconductor substrate 110 may be wholly passivated, and may be easily formed without separate patterning. Each of the first and second passivation layers 52 and 54 may have a thickness ranging from 2 nm to 8 nm.

The first conductive area 20 of a first conductive type may be formed on the first passivation layer 52. The second conductive area 30 of a second conductive type, which is the opposite of the first conductive type, may be formed on the second passivation layer 54.

In the present disclosure, the first conductive area 20 is not formed in the first and second edge areas EA1 and EA2 on the first surface of the semiconductor substrate 110, but is formed in the cell area CA on the first surface. Unlike this, the second conductive area 30 may be formed in all of the first and second edge areas EA1 and EA2 and the cell area CA on the second surface of the semiconductor substrate 110.

The first conductive area 20 may be a first conductive area including a first conductive dopant. In addition, the second conductive area 30 may be a second conductive area including a second conductive dopant. In one example, the first conductive area 20 may come into contact with the first passivation layer 52, and the second conductive area 30 may come into contact with the second passivation layer 54. As such, the structure of the solar cell 100 may be simplified, and the tunneling effect of the first and second passivation layers 52 and 54 may be maximized. However, the present disclosure is not limited thereto.

Since the first conductive area 20 and the second conductive area 30 are formed on the semiconductor substrate 160 separately from the semiconductor substrate 160, the first conductive area 20 and the second conductive area 30 may have a different material and/or crystalline structure from that of the semiconductor substrate 110, in order to be easily formed on the semiconductor substrate 110.

For example, each of the first conductive area 20 and the second conductive area 30 may be formed by doping, for example, an amorphous semiconductor layer, which may be easily manufactured via any of various methods, such as, for example, deposition, with a first or second conductive dopant. As such, the first conductive area 20 and the second conductive area 30 may be easily formed via a simplified process. At this time, when the first and second passivation layers 52 and 54 are formed of intrinsic semiconductor substrate (e.g., intrinsic amorphous silicon) as described above, for example, excellent adhesion and excellent electrical conductivity may be acquired.

In addition, a p-type dopant, used as the first or second conductive dopant, may be a group-III element, such as boron (B), aluminum (Al), gallium (ga), or indium (In), and an n-type dopant may be a group-V element, such as phosphorus (P), arsenic (As), bismuth (Bi), or antimony (Sb). However, the present disclosure is not limited thereto, and various other dopants may be used as the first or second conductive dopant.

In one example, the semiconductor substrate 110 and the first conductive area 20, which are of the first conductive type, may be of an n-type, and the second conductive area 30 may be of a p-type. Thereby, the n-type semiconductor substrate 110 may provide an excellent carrier lifetime. In this case, the semiconductor substrate 110 and the first conductive area 20 may include phosphorus (P) as the n-type dopant, and the second conductive area 30 may include boron (B) as the p-type dopant. However, the present disclosure is not limited thereto, and the semiconductor substrate 110 and the first conductive area 20 of the first conductive type may be of a p-type and the second conductive area 30 may be of an n-type.

In the present implementation, each of the first conductive area 20 and the second conductive area 30 may include at least one of an amorphous silicon (a-Si) layer, an amorphous silicon oxide (a-SiOx) layer, and an amorphous silicon carbide (a-SiCx) layer.

At this time, the amorphous silicon (a-Si) layer, the amorphous silicon oxide (a-SiOx) layer, or the amorphous silicon carbide (a-SiCx) layer, which is applied to the first conductive ara 20 or the second conductive area 30, may be doped with the first or second conductive dopant.

Among these, the amorphous silicon oxide (a-SiOx) layer and the amorphous silicon carbide (a-SiCx) layer may have a high energy band gap to ensure sufficient energy band bending, thereby being capable of selectively passing carriers.

In addition, the second conductive area 30 may include at least one of an amorphous silicon (a-Si) layer, an amorphous silicon oxide (a-SiOx) layer, and an amorphous silicon carbide (a-SiCx) layer. Since the second conductive area 30 may form, along with the semiconductor substrate 110, a p-n junction to participate in photoelectric conversion. In some implementations, the second conductive area 30 and the semiconductor substrate 110 can form a pin junction with the second passivation layer 54 interposed between the second conductive area 30 and the semiconductor substrate 110 to participate in photoelectric conversion. The second conductive area 30 may include the same semiconductor material (e.g., silicon) as the semiconductor substrate 110 so as to have properties similar to those of the semiconductor substrate 110, thereby ensuring the more effective movement of carriers.

Meanwhile, the first conductive area 20 or the second conductive area 30 may be formed of a metal compound, for example, a metal oxide layer.

In one example, the metal oxide layer, which may be used as the first conductive area 30, may be at least one of a molybdenum oxide layer formed of a molybdenum oxide, a tungsten oxide layer formed of a tungsten oxide (e.g., WO₃), a vanadium oxide layer formed of a vanadium oxide (e.g., V₂Oₓ), a titanium oxide layer formed of a titanium oxide (e.g., TiO₂), a nickel oxide layer formed of a nickel oxide (e.g., NiO), a copper oxide layer formed of a copper oxide (CuO), a rhenium oxide layer formed of a rhenium oxide (e.g., ReO₃), a tantalum oxide layer formed of a tantalum oxide (e.g., TaOₓ), and a hafnium oxide layer formed of a hafnium oxide (e.g., HfO₂).

In particular, when the first conductive area 30 includes a molybdenum oxide layer or a tungsten oxide layer, the first conductive area 30 may exhibit the excellent effect of selectively collecting holes. Meanwhile, the metal compound layer, which may be used as the second conductive area 30, may be a metal oxide layer including at least one of a titanium oxide layer formed of a titanium oxide (e.g., TiO₂), a zinc oxide layer formed of a zinc oxide (e.g., ZnO), a tin oxide layer formed of a tin oxide (e.g., SnO₂), and a zirconium oxide layer formed of a zirconium oxide (e.g., ZrO).

In particular, when the second conductive area 30 includes a titanium oxide layer, the second conductive area 34 may exhibit the excellent effect of selectively collecting electrons.

However, the metal oxide included in the first conductive area 30 or the second conductive area 30 is not limited to the aforementioned metal oxides. The first conductive area 20 may include the aforementioned metal oxide included in the second conductive area 30, and the second conductive area 30 may include the aforementioned metal oxide included in the first conductive area 20.

Each of the first and second conductive areas 20 and 30 may have a thickness ranging from 5 nm to 15 nm.

The first electrode 42 may be disposed on (e.g., in contact with) the first conductive area 20 so as to be electrically connected thereto, and the second electrode 44 may be disposed on (e.g., in contact with) the second conductive area 30 so as to be electrically connected thereto.

The first electrode 42 may include a first transparent electrode layer 421 and a first metal electrode layer 422, which are sequentially stacked one above another on the first conductive area 20.

Here, the first transparent electrode layer 421 may be formed over (e.g., in contact with) the entire first conductive area 20. The term “entire” includes not only the case where the entire first conductive area 20 is covered without leaving an empty space or an empty area, but also the case where a portion of the first conductive area 20 is inevitably excluded. When the first transparent electrode layer 421 is formed over the entire first conductive area 20, carriers may easily reach the first metal electrode layer 422 by passing through the first transparent electrode layer 421, which may result in reduced resistance in the horizontal direction. Because the first conductive area 20, which is configured as an amorphous semiconductor layer, may have relatively low crystallinity, and thus may reduce the mobility of carriers, the provision of the first transparent electrode layer 421 may reduce resistance when carriers move in the horizontal direction.

Because the first transparent electrode layer 421 is formed over the entire first conductive area 20, the first transparent electrode layer 421 may be formed of a material capable of transmitting light (i.e. a light-transmitting material). That is, the first transparent electrode layer 421 may be formed of a transparent conductive material to enable the transmission of light and the easy movement of carriers. Thereby, even when the first transparent electrode layer 421 is formed on the entire first conductive area 20, the transmission of light may not be blocked.

In one example, the first transparent electrode layer 421 may include at least one of indium tin oxide (ITO), aluminum zinc oxide (AZO), boron zinc oxide (BZO), indium tungsten oxide (IWO), and indium cesium oxide (ICO). However, the present disclosure is not limited thereto, and the first transparent electrode layer 421 may include any of various other materials.

At this time, the first transparent electrode layer 421 of the present implementation may include any of the aforementioned materials, which is a main material, and may further include hydrogen. That is, the first transparent electrode layer 421 may include at least one of indium tin oxide including hydrogen (ITO:H), aluminum zinc oxide including hydrogen (AZO:H), boron zinc oxide including hydrogen (BZO:H), indium tungsten oxide including hydrogen (IWO:H), and indium cesium oxide including hydrogen (ICO:H).

The first transparent electrode layer 421 may be formed by deposition. When hydrogen gas is introduced during deposition, the first transparent electrode layer 421 may include hydrogen. When the first transparent electrode layer 421 includes hydrogen, the mobility of electrons or holes may be improved, and the transmittance of light may be improved.

In the present implementation, the first metal electrode layer 422 having a pattern may be formed on the first transparent electrode layer 421. In one example, the first metal electrode layer 422 may be in contact with the first transparent electrode layer 421 so as to simplify the structure of the first electrode 42. However, the present disclosure is not limited thereto, and various modifications, such as, for example, a modification in which a separate layer is present between the first metal electrode layer 422 and the first transparent electrode layer 421, are possible.

The first metal electrode layer 422 disposed on the first transparent electrode layer 421 may be formed of a material having higher electrical conductivity than the first transparent electrode layer 421. Thereby, the first metal electrode layer 422 may achieve, for example, an increased carrier collection efficiency and a reduced resistance. In one example, the first metal electrode layer 422 may be formed of a metal that has excellent electrical conductivity and is opaque or has a lower transparency than the first transparent electrode layer 421.

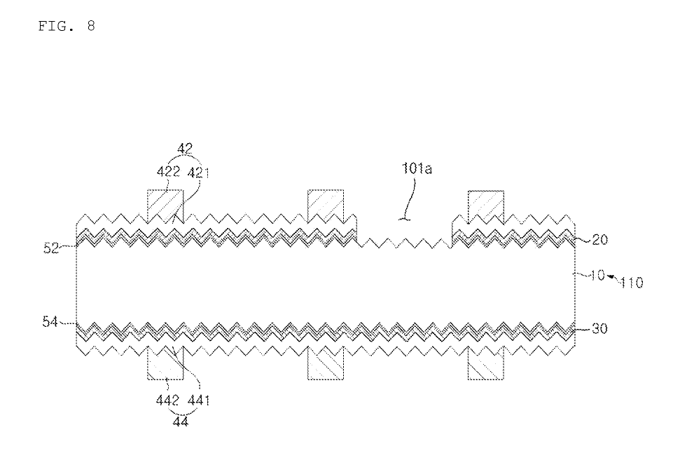

Since the first metal electrode layer 422 may be opaque or have low transparency, and thus may prevent the introduction of light, the first metal electrode layer 422 may have a given pattern in order to minimize shading loss. Thereby, light may be introduced into the portion in which no metal electrode layer 422 is formed. The plan shape of the first metal electrode layer 422 will be described later in more detail with reference to FIG. 7.

The second electrode 44 may include a second transparent electrode layer 441 and a second metal electrode layer 442, which are sequentially stacked one above another on the second conductive area 30. Except for that the second electrode 44 is disposed on the second conductive area 30, for example, the role, material, and shape of the second transparent electrode layer 441 and the second metal electrode layer 442 may be the same as the role, material, and shape of the first transparent electrode layer 421 and the first metal electrode layer 422, and thus the description related to the first transparent electrode layer 421 and the first metal electrode layer 422 may be equally applied to the second transparent electrode layer 441 and the second metal electrode layer 442.

In the present implementation, the metal electrode layers 422 and 442 of the first and second electrodes 42 and 44 may include a conductive material and a resin (e.g., a binder, a curing agent, or an additive). The conductive material may include, for example, silver (Ag), aluminum (Al), or copper (Cu), and the resin may include, for example, a cellulose-based or phenolic-based binder, or an amine-based curing agent.

In addition, when low-temperature firing (e.g., firing at a processing temperature of 300° C. or less) is required, glass frit may not be included. Meanwhile, the first and second metal electrode layers 422 and 442 may be formed by plating.

In the present implementation, the first and second edge areas EA1 and EA2 on the first surface of the semiconductor substrate 110 may be exposed because no semiconductor layer is formed thereon. The first and second edge areas EA1 and EA2 of the first surface of the semiconductor substrate 110 may have a consistent foreign substance doping concentration in the depth direction thereof. That is, no foreign substance may be diffused in the first surface of the semiconductor substrate 110 including the first conductive area 20, which may increase the reliability and efficiency of the solar cell 100.

However, the technical sprit of the present disclosure is not limited thereto, and in another implementation of the present disclosure, a semiconductor layer may be formed on the first and second edge areas EA1 and EA2 on the first surface of the semiconductor substrate 110. A detailed description will be provided later.

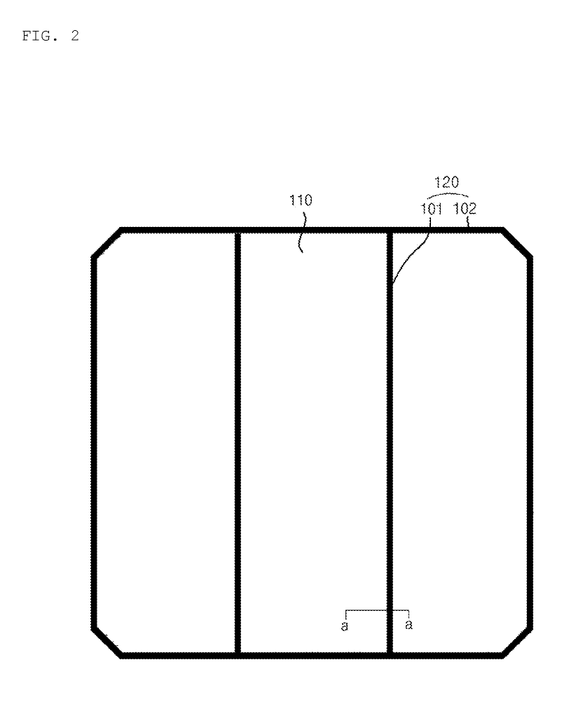

Next, a method of manufacturing the solar cell according to some implementations of the present disclosure will be described with reference to FIGS. 2 to 11.

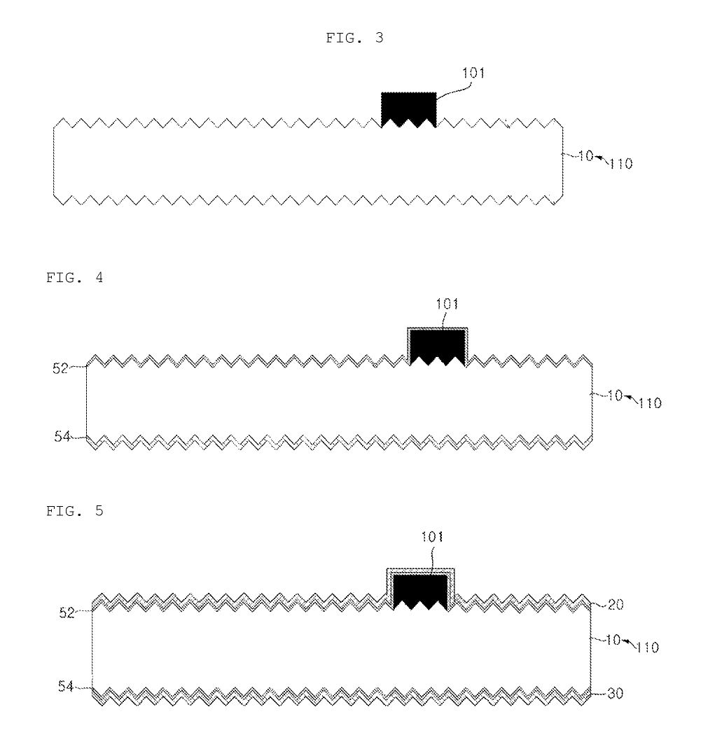

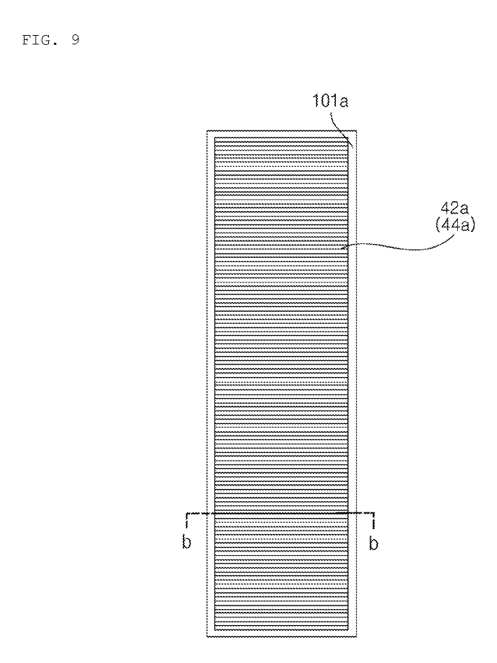

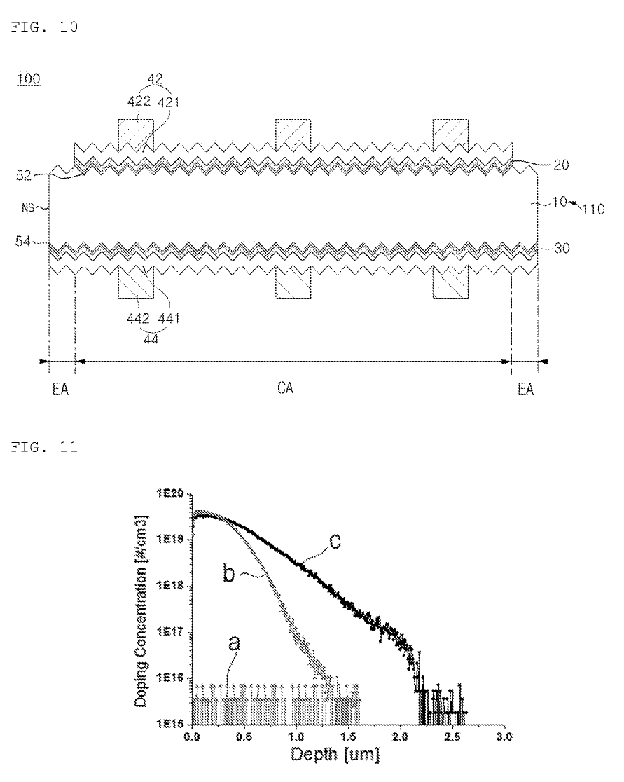

FIGS. 2 to 11 are cross-sectional views and plain views for explaining a method of manufacturing the solar cell according to some implementations of the present disclosure. FIG. 2 is a plain view for explaining the method of manufacturing the solar cell, and FIGS. 3 to 6 are cross-sectional views taken along line A-A of FIG. 2. FIG. 7 is a plain view for explaining the method of manufacturing the solar cell, and FIG. 8 is a cross-sectional view of FIG. 7 taken along the same direction as line A-A of FIG. 2. FIG. 9 is a plain view for explaining the method of manufacturing the solar cell, and FIG. 10 is a cross-sectional view taken along line a-b.

Referring to FIGS. 2 and 3, a mask 120 is disposed on the semiconductor substrate 110 including the base area 10. The mask 120 includes an edge portion 102 and a line portion 101. The edge portion 102 of the mask 120 may be disposed on the rim, i.e. an edge portion of the semiconductor substrate 110, and the line portion 101 may be disposed on the area of the semiconductor substrate 110 in which a scribing process will be performed later, i.e. a scribing portion of the semiconductor substrate 110.

In the present implementation, although the mask 120 is illustrated as including two line portions 101, the technical sprit of the present disclosure is not limited thereto. Thus, the mask 120 may include one line portion 101 or three or more line portions 101, and the number of line portions may be appropriately adjusted according to the number of portions into which the semiconductor substrate 110 will be divided.

The mask 120 may be formed of any of various materials having structural rigidity, for example, a curable polymer material. The constituent material of the mask 120 may not be particularly limited so long as it has rigidity required to separate a semiconductor layer that is disposed on the mask 120 from a semiconductor layer that is not disposed on the mask 120 in a following process.

Referring again to FIG. 3, the line portion 101 of the mask 120 may have a rectangular cross section. Although a semiconductor layer disposed on the mask 120 may be easily separated when the mask 120 has a rectangular cross section, the present disclosure is not limited thereto, and the mask 120 may have a polygonal cross section including a triangular cross section, or may have a circular cross section. In addition, the width of the line portion 101 may range from 4 mm to 10 mm, without being limited thereto.

Referring to FIG. 4, the first passivation layer 52 is formed on the first surface of the semiconductor substrate 110 and the line portion 101, and the second passivation layer 54 is formed on the second surface of the semiconductor substrate 110.

The first and second passivation layers 52 and 54 may be formed by, for example, thermal growth or deposition (e.g., chemical vapor deposition (PECVD) or atomic layer deposition (ALD)). However, the present disclosure is not limited thereto, and the first and second passivation layers 52 and 54 may be formed by various other methods. The first and second passivation layers 52 and 54 may be formed simultaneously or sequentially.

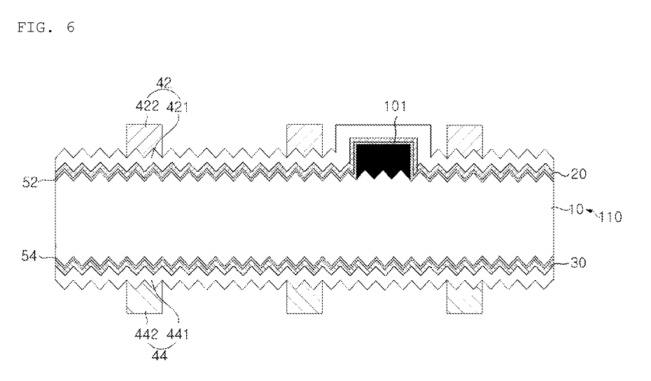

Subsequently, referring to FIG. 5, the first conductive area 20 and the second conductive area 30 are formed on the first and second passivation layers 52 and 54. More specifically, the first conductive area 20 is formed on the first passivation layer 52, and the second conductive area 30 is formed on the second passivation layer 54.

The first conductive area 20 and the second conductive area 30 may be formed by, for example, thermal growth or deposition (e.g., chemical vapor deposition (PECVD) or atomic layer deposition (ALD)). A first or second conductive dopant may be included in a process of growing a semiconductor layer including the first conductive area 20 and the second conductive area 30, or may be doped by, for example, ion implantation, thermal diffusion, or laser doping after the semiconductor layer is formed. However, the present disclosure is not limited thereto, and the first conductive area 20 and the second conductive area 30 may be formed by various other methods. The first conductive area 20 and the second conductive area 30 may be formed simultaneously, and then be doped, or may be deposited sequentially and/or doped.

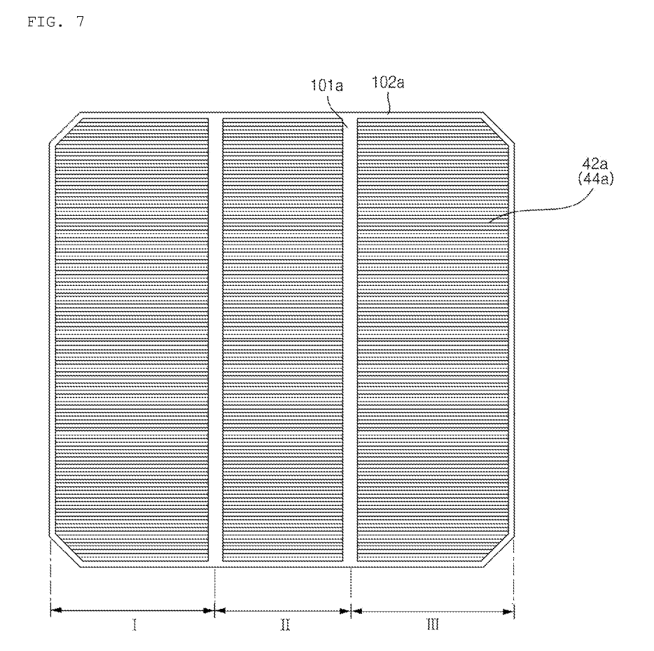

Subsequently, referring to FIG. 6, the first and second electrodes 42 and 44 are formed on the first conductive area and the second conductive area 30. Specifically, the first and second transparent electrode layers 421 and 441 are formed on the first conductive area 20 and the second conductive area 30, and the first and second metal electrode layers 422 and 442 are formed on the first and second transparent electrode layers 421 and 441.

The first and second transparent electrode layers 421 and 441 may be formed by, for example, deposition (e.g., chemical vapor deposition (PECVD)) or coating. However, the present disclosure is not limited thereto, and the first and second transparent electrode layers 421 and 441 may be formed by various other methods.

In one example, the first and second transparent electrode layers 421 and 441 may be formed by introducing a raw material, which is a main constituent material, and a mixed gas of hydrogen gas (H₂) and carrier gas (e.g., argon gas (Ar) or nitrogen gas (N₂)). Thereby, hydrogen may be included in the first and second transparent electrode layers 421 and 441 so as to realize any relevant effect.

The first and second metal electrode layers 422 and 442 are formed on the first and second transparent electrode layers 421 and 441.

Subsequently, a first low-temperature paste layer is formed on one of the first conductive area 20 and the second conductive area 30 (more specifically, on the first and second transparent electrode layers 421 and 441), and is dried to form one of the first and second metal electrode layers 422 and 442. A second low-temperature paste layer is formed on the other one of the first conductive area 20 and the second conductive area 30, and is dried to form the other one of the first and second metal electrode layers 422 and 442. However, the present disclosure is not limited thereto, and the first and second low-temperature paste layers may be simultaneously formed on the opposite sides and then be simultaneously dried.

Subsequently, referring to FIGS. 7 and 8, the mask 120 is removed to expose the semiconductor substrate 110. When the mask 120 is removed, an exposed space 101a is formed. Since the portions of the first passivation layer 52, the first conductive area 20, and the first transparent electrode layer 421, which are disposed on the mask 102, are removed, simultaneously with the removal of the mask 102, the exposed space 101a is formed. The semiconductor substrate 110 is exposed through the exposed space 101a. A portion of the semiconductor substrate 110 corresponding to the exposed space 101a is a scribing portion of the semiconductor substrate 110.

First, the first and second metal electrode layers 421 and 441 will be described with reference to FIG. 7.

Referring to FIG. 7, the first and second metal electrode layers 422 and 442 may respectively include a plurality of finger lines 42a and 44a, which are spaced apart from one another at a constant pitch. Although FIG. 7 illustrates the finger lines 42a and 44a as being parallel to each other and also being parallel to the edge of the semiconductor substrate 110, the present disclosure is not limited thereto. In addition, the first and second metal electrode layers 422 and 442 may include bus-bars, which are formed to intersect the finger lines 42a and 44a so as to connect the finger lines 42a and 44a. One bus-bar may be provided, or a plurality of bus-bars may be provided at a larger pitch than the pitch of the finger lines 42a and 44a. Meanwhile, in the present implementation, for brief illustration, the bus-bar is not illustrated in FIG. 7.

Meanwhile, when the first metal electrode layer 422 is formed, it may not be formed in the exposed space 101a. That is, as illustrated in FIG. 6, the first metal electrode layer 422 is not formed on the mask 102. Thereby, it is possible to prevent the first metal electrode layer 422 from being excessively removed when the mask 102 is removed.

Meanwhile, in the present implementation, although the exposed space 101a is illustrated as being formed in the location at which it intersects the finger line 42a, the exposed space 101a may be formed to intersect the bus-bar when the first metal electrode layer 422 is formed. In this case, no bus-bar is formed on the mask 102.

Meanwhile, in the present implementation, although the sidewalls of the first passivation layer 52, the first conductive area 20, and the first transparent electrode layer 421, which are exposed through the exposed space 101a, are successively formed, the present disclosure is not limited thereto. Thus, the sidewalls of the first passivation layer 52, the first conductive area 20, and the first transparent electrode layer 421 may be discontinuously formed.

Meanwhile, referring again to FIG. 7, the semiconductor substrate 110 includes a first area I, a second area II, and a third area III. The first area I, the second area II, and the third area III may have the same area. That is, when the semiconductor substrate 110 is divided on the basis of the exposed space 101a, the divided first area I, second area II, and third area III of the semiconductor substrate 110 may have the same area.

Subsequently, referring to FIGS. 9 and 10, the semiconductor substrate 110 is divided on the basis of the exposed space 101a.

Specifically, a scribing process may be performed by irradiating the exposed space 101a with a laser.

The scribing process may be performed via a laser device including a chuck table. The laser device includes a laser emitter, and the laser emitter may adjust, for example, the frequency, power, and pulse width of a laser beam. The laser device may emit a laser beam having a specific power and pulse width to the exposed space 101a in the semiconductor substrate 110 through a light collector. The laser device may include a separate alignment unit, and the alignment unit may perform positioning between the scribing portion including the exposed space 101a and the light collector of the laser device that emits the laser beam along the scribing portion.

In this way, the solar cell 100 illustrated in FIGS. 9 and 10 may be manufactured. The solar cell illustrated in FIG. 9 may correspond to the second area II of FIG. 7. The solar cell 100 includes the first and second edge areas EA1 and EA2 and the cell area CA, as described above with reference to FIG. 1. The first and second edge areas EA1 and EA2 correspond to the above-described exposed space 101a. Thus, since the first and second edge areas EA1 and EA2 undergo surface modification due to laser irradiation, the semiconductor substrate 110, which is exposed through the edge area EA on the first surface thereof, includes a laser-damaged area. Thus, the edge areas EA of the first surface and the second surface of the semiconductor substrate 110 may have different crystalline structures, and specifically, the first and second edge areas EA1 and EA2 of the first surface of the semiconductor substrate 110 may have a larger crystalline structure.

Meanwhile, although the cut semiconductor substrate 110 is illustrated in FIG. 9 as having a short horizontal side and a long vertical side, the technical sprit of the present disclosure is not limited thereto. That is, the cut semiconductor substrate 110 may of course have a long horizontal side and a short vertical side. Meanwhile, although the scribing process using a laser has been described in the present implementation, the present disclosure is not limited thereto, and the semiconductor substrate 110 may be separated via any of various processes such as, for example, a separation process using a diamond cutter.

Meanwhile, in the present implementation, when a laser is used in the scribing process, the laser is directly emitted to the semiconductor substrate 110. Thus, compared to a conventional case where a laser is emitted to the semiconductor substrate 110 having a semiconductor layer formed thereon, the semiconductor substrate 110 has a more uniform foreign substance doping concentration in the depth direction thereof.

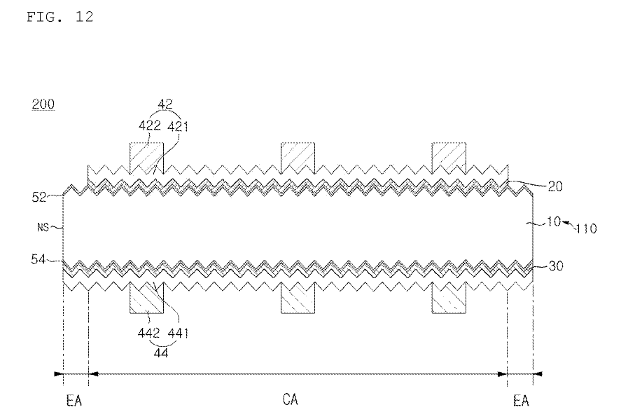

FIG. 11 is a graph illustrating the doping concentration of the semiconductor substrate in the depth direction according to the present disclosure and the related art.

The line “a” shows the doping concentration of the semiconductor substrate 110 in the depth direction according to the present disclosure, and the lines “b” and “c” show the doping concentration of the semiconductor substrate 110 in the depth direction according to the related art. Here, the line “a” indicates the case where a laser having a power of 18W is emitted, the line “a” indicates the case where a laser having a power of 18W is emitted, and the line “c” indicates the case where a laser having a power of 25W is emitted.

Considering the line “a” according to the present disclosure with reference to FIG. 11, it can be seen that the semiconductor substrate 110 has uniform doping concentration in the depth direction thereof. Unlike this, in the related art, a semiconductor substrate is subjected to scribing when a laser is emitted to the semiconductor substrate having a semiconductor layer formed thereon. Thus, referring to the line “b” and the line “c” of the related art, it can be seen that the doping concentration varies in the depth direction. In addition, in the related art, since a foreign substance included in a conductive area diffuses to the semiconductor substrate via laser irradiation, it can be seen that the doping concentration is higher in the surface of the semiconductor substrate, compared to the present disclosure.

In the present disclosure, since laser irradiation for scribing the semiconductor substrate is directly performed on the semiconductor substrate 110 through the exposed space 101a, it is possible to prevent the foreign substance included in the conductive area from diffusing to the surface of the semiconductor substrate 110. In addition, compared to the conventional case where the laser is emitted to the semiconductor layer, it is possible to prevent the generation of foreign substances such as particles. Thereby, the solar cell manufactured according to the present implementation may achieve increased reliability and performance.

Next, a solar cell according to some implementations of the present disclosure will be described with reference to FIG. 12.

FIG. 12 is a cross-sectional view illustrating a solar cell according to some implementations of the present disclosure.

The solar cell of the present implementation is substantially the same as the solar cell described with reference to FIG. 1, except that the first passivation layer 52 is exposed through the edge area EA on the first surface of the semiconductor substrate 110. Thus, the same reference numerals designate the same elements, and a repeated description thereof will be omitted.

Referring to FIG. 12, the solar cell 200 according to the present implementation may include the semiconductor substrate 110 including the base area 10, the first passivation layer 52 formed on the first surface of the semiconductor substrate 110, the second passivation layer 54 formed on the second surface of the semiconductor substrate 110, the first conductive area 20 formed on the first passivation layer 52 at the first surface side of the semiconductor substrate 110, the second conductive area 30 formed on the second passivation layer 54 at the second surface side of the semiconductor substrate 110, the first electrode 42 electrically connected to the first conductive area 20, and the second electrode 44 electrically connected to the second conductive area 30.

In the present implementation, the first passivation layer 52 may be formed on the entire first surface of the semiconductor substrate 110. Thus, the passivation effect of the semiconductor substrate 110 may be improved.

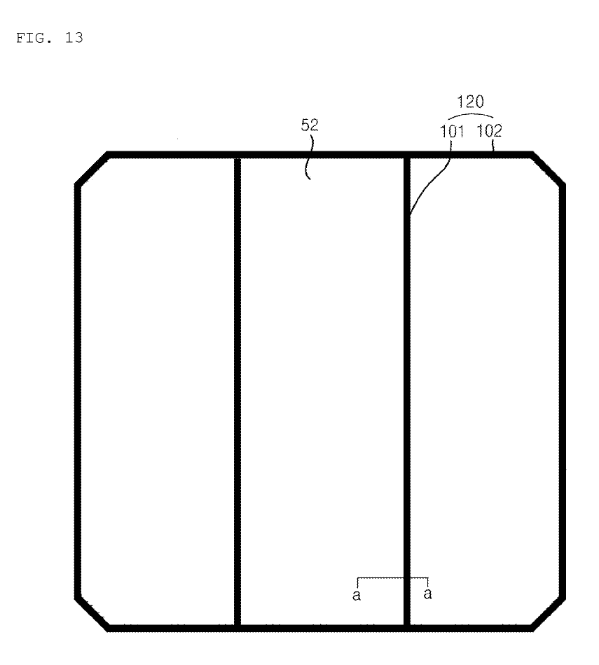

Next, a method of manufacturing the solar cell according to some implementations of the present disclosure will be described with reference to FIGS. 13 to 18.

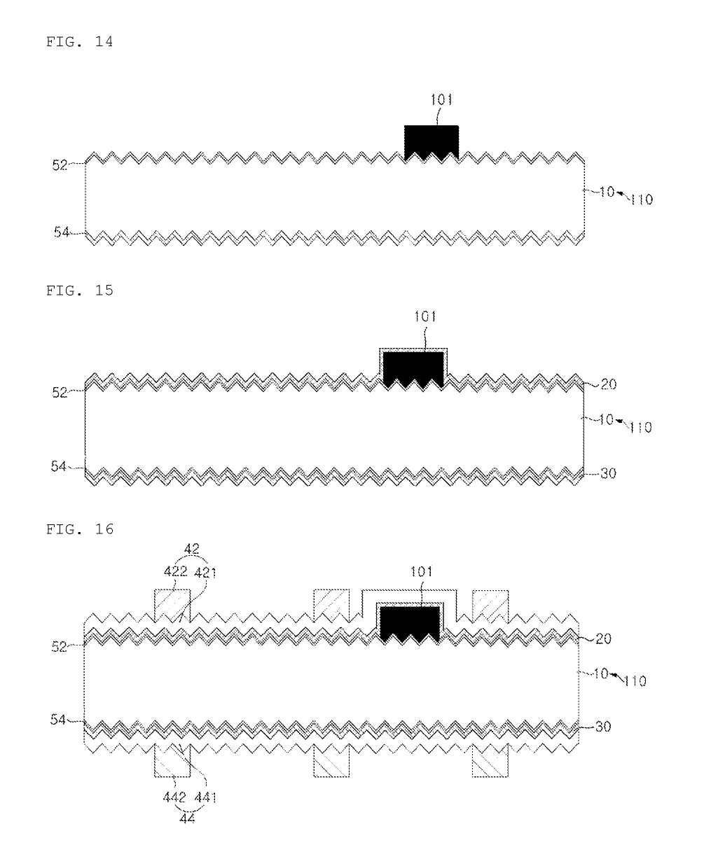

FIGS. 13 to 18 are cross-sectional views and plain views for explaining a method of manufacturing the solar cell according to some implementations of the present disclosure. FIG. 13 is a plain view illustrating an intermediate step of the solar cell manufacturing method, and FIG. 14 is a cross-sectional view taken along line a-a of FIG. 13.

The solar cell manufacturing method according to the present implementation is substantially the same as the solar cell manufacturing method described above with reference to FIGS. 2 to 11, except that the mask 120 is disposed on the first passivation layer 52. Thus, the same reference numerals designate the same elements, and a repeated description thereof will be omitted.

Referring to FIGS. 13 and 14, the mask 120 is disposed on the semiconductor substrate 110 having the first passivation layer 52 formed thereon.

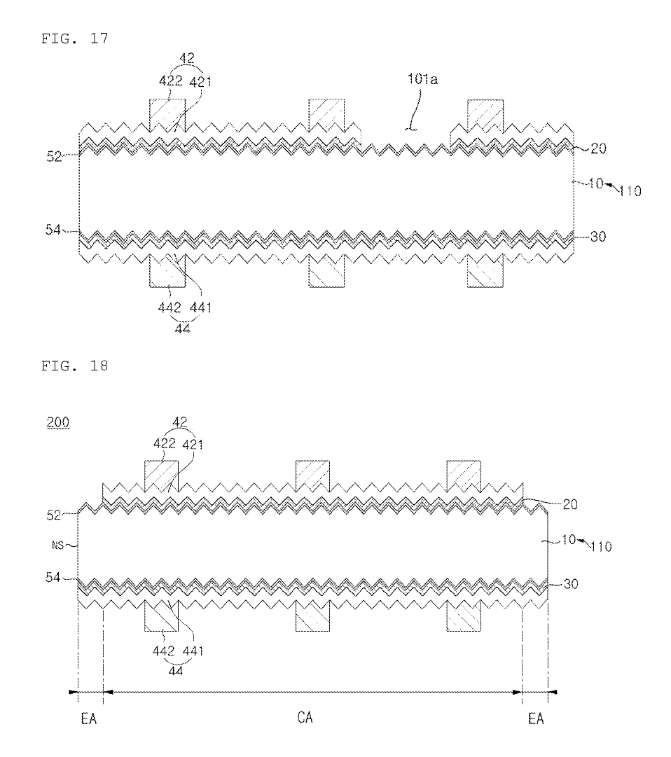

Subsequently, referring to FIG. 15, the first conductive area 20 is formed on the first surface of the semiconductor substrate 110, and the second conductive area 30 is formed on the second surface. At this time, the first conductive area 20 may be directly formed on the upper surface and the sidewall of the line portion 101 of the mask 120.

Subsequently, referring to FIG. 16, the first electrode 42 is formed on the first conductive area 20, and the second electrode 44 is formed on the second conductive area 30.

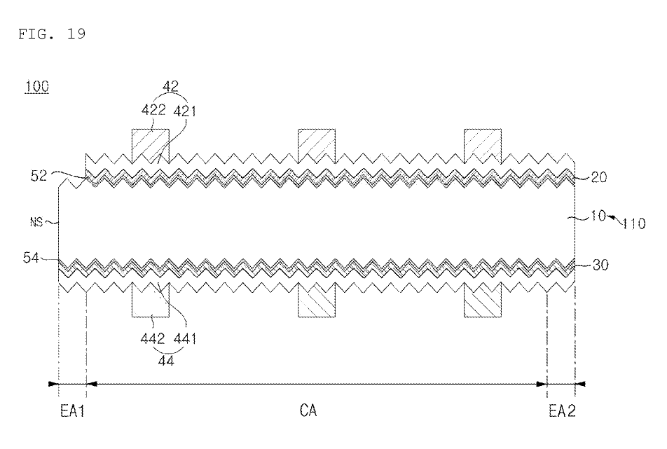

Subsequently, referring to FIG. 17, the line portion 101 of the mask 120 is removed to form the exposed space 101a that exposes the first passivation layer 52.

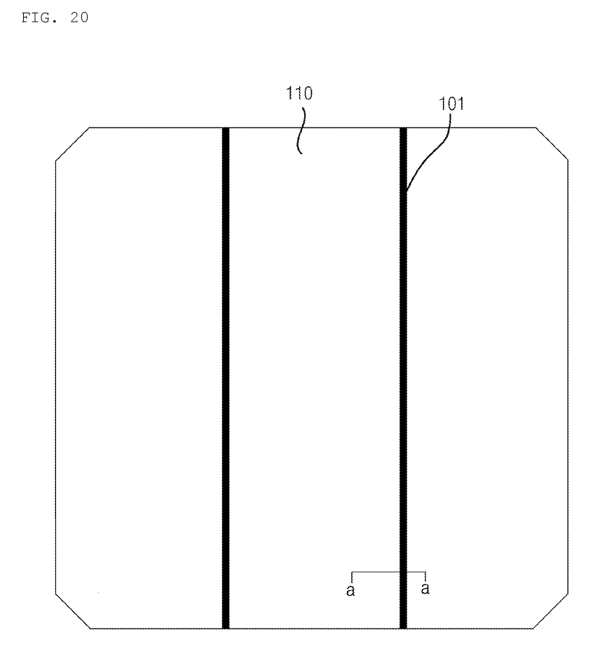

When the semiconductor substrate 110 may be separated along the exposed space 101a, the solar cell 200 may be formed as illustrated in FIG. 18.

Since the solar cell 200 according to the present implementation includes the first passivation layer 52 formed on the entire first surface of the semiconductor substrate 110, the passivation effect thereof may be more improved. The first passivation layer 52 includes an intrinsic semiconductor layer having no foreign substance. Thus, the solar cell 200 may have uniform foreign substance doping concentration in the depth direction of the semiconductor substrate 110, as illustrated in FIG. 11.

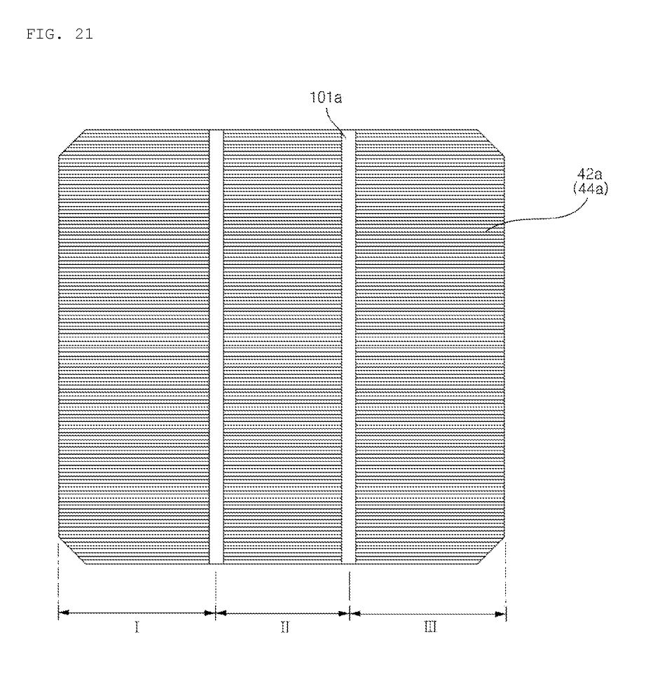

Next, a solar cell according to some implementations of the present disclosure will be described with reference to FIG. 19.

The solar cell of the present implementation is substantially the same as the solar cell described with reference to FIG. 1, except that the second edge area EA2 of the first surface is not exposed. Thus, a repeated description thereof will be omitted.

In the solar cell according to the present implementation, the second edge area EA2 of the first surface is not exposed. This configuration may be realized when the mask used in the solar cell manufacturing method includes no edge portion. This will be described in more detail with reference to FIGS. 20 to 23.

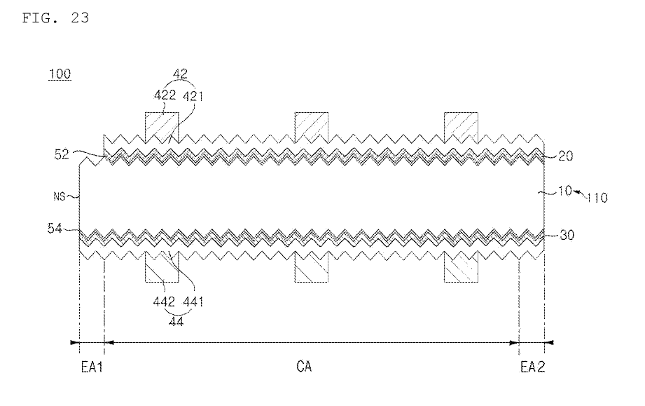

FIGS. 20 to 23 are cross-sectional views and plain views for explaining a method of manufacturing the solar cell according to some implementations of the present disclosure. FIG. 23 is a cross-sectional view taken along line b-b of FIG. 22.

The solar cell manufacturing method according to the present implementation is substantially the same as the solar cell manufacturing method described above with reference to FIGS. 2 to 11, except that the mask includes no edge portion. Thus, a repeated description thereof will be omitted, and the following description will be focused on only differences.

Referring to FIG. 20, the mask 101 according to the present implementation may be located so as to correspond to the scribing portion of the semiconductor substrate 110.

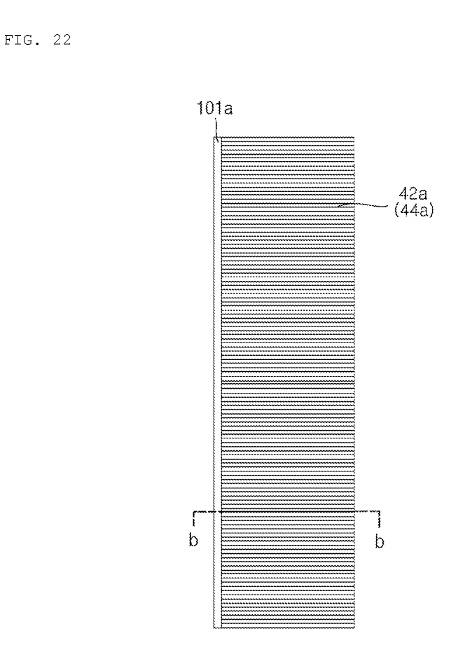

Thereby, referring to FIG. 21, the exposed space 101a, which exposes the semiconductor substrate 110, may be formed only in the semiconductor substrate 110, and may not be formed in any external portion that is adjacent to the side surface of the semiconductor substrate 110.

Accordingly, after the semiconductor substrate 110 is divided as illustrated in FIG. 21, referring to the solar cell of FIGS. 22 and 23, which corresponds to the third area III of FIG. 21, the first edge area EA1 of the solar cell 100 is exposed, whereas the second edge area EA2 is not exposed.

Meanwhile, solar cells manufactured via division of the semiconductor substrate 110 according to the present implementation may be electrically interconnected in series and/or in parallel via interconnectors, or may be interconnected so that specific areas thereof overlap each other. Thereby, the multiple solar cells may construct a solar cell panel.

The above described features, configurations, effects, and the like are included in at least one of the implementations of the present disclosure, and should not be limited to only one implementation. In addition, the features, configurations, effects, and the like as illustrated in each implementation may be implemented with regard to other implementations as they are combined with one another or modified by those skilled in the art. Thus, content related to these combinations and modifications should be construed as including in the scope and spirit of the disclosure as disclosed in the accompanying claims.

What is claimed is:

1. A solar cell comprising:
a semiconductor substrate including a first surface and a second surface that is different the first surface, wherein each of the first surface and the second surface includes a first edge area, a second edge area, and a cell area that is located between the first edge area and the second edge area;
a first passivation layer that is formed on the cell area of the first surface of the semiconductor substrate;
a first conductive semiconductor layer that is disposed on the first passivation layer; and
a first electrode that is coupled to the first conductive semiconductor layer,
wherein the first edge area of the first surface of the semiconductor substrate includes an exposed area, and
wherein a portion of the semiconductor substrate corresponding to the exposed area has a uniform doping concentration in a first direction.

2. The solar cell of claim 1, wherein the second edge area of the first surface is exposed.

3. The solar cell of claim 1, further comprising:
a second passivation layer that is disposed on the first edge area, the second edge area, and the cell area of the second surface of the semiconductor substrate;
a second conductive semiconductor layer disposed on the second passivation layer, a conductive type of the second conductive semiconductor layer being different from a conductive type of the first conductive semiconductor layer; and
a second electrode that is coupled to the second conductive semiconductor layer.

4. The solar cell of claim 3, wherein the second conductive semiconductor layer includes an emitter layer, wherein the emitter layer and the semiconductor substrate forms a p-n junction.

5. The solar cell of claim 1, wherein the first edge area and the second edge area of the second surface of the semiconductor substrate include non-exposed areas.

6. The solar cell of claim 1, wherein the first edge area of the first surface includes a laser-damaged area.

7. The solar cell of claim 6, wherein the first edge area of the first surface of the semiconductor substrate include a first crystalline structure, and
wherein the first edge area of the second surface of the semiconductor substrate includes a second crystalline structure that is different from the first crystalline structure.

8. The solar cell of claim 1, wherein the first passivation layer covers at least a portion of the exposed area of the first edge area of the first surface of the semiconductor substrate.

9. The solar cell of claim 1, wherein the first edge area of the first surface of the semiconductor substrate is coupled to the second edge area of the first surface of the semiconductor substrate.

10. A method of manufacturing a solar cell, the method comprising:
disposing a mask on a scribing portion of a semiconductor substrate, wherein the semiconductor substrate includes a plurality of cell portions and the scribing portion is located between a first cell portion and a second cell portion of the plurality of cell portions;
forming a first conductive area on the semiconductor substrate and the mask;
forming a first electrode on the first conductive area, the first electrode being electrically coupled to the first conductive area;
removing the mask to remove a portion of the first conductive area that is disposed on the mask; and
dividing the semiconductor substrate along the scribing portion of the semiconductor substrate.

11. The method of claim 10, further comprising:
disposing the mask on an edge area that is formed on a surface of the semiconductor substrate and that is adjacent to a side surface of the semiconductor substrate.

12. The method of claim 10, wherein the semiconductor substrate is exposed through the scribing portion of the semiconductor substrate by removing the mask.

13. The method of claim 11, wherein dividing the semiconductor substrate includes:
irradiating the scribing portion of the semiconductor substrate with a laser.

14. The method of claim 13, wherein the scribing portion of the semiconductor substrate has a uniform doping concentration in a first direction.

15. The method of claim 13, wherein the semiconductor substrate has a first conductive type, and
wherein the first conductive area has the first conductive type.

16. The method of claim 10, wherein forming the first electrode includes:
forming a first transparent electrode layer, and
forming a first metal electrode layer on the first transparent electrode layer, and
wherein forming the first metal electrode layer includes:
forming the first metal electrode layer on the cell portions of the semiconductor substrate without forming the first metal electrode layer on the scribing portion of the semiconductor substrate.

17. The method of claim 10, further comprising:
forming a first passivation layer on the semiconductor substrate before disposing the mask,
wherein removing the mask includes:
removing the mask to expose a portion of the first passivation layer that is disposed on the scribing portion of the semiconductor substrate.

18. The method of claim 17, wherein dividing the semiconductor substrate includes:
irradiating a portion of the first passivation layer with a laser through the scribing portion of the semiconductor substrate.

19. The method of claim 17, wherein the first passivation layer includes an intrinsic semiconductor layer.

20. The method of claim 10, wherein dividing the semiconductor substrate includes:
dividing the semiconductor substrate into two or more divided semiconductor substrates that have a first area.
